(19) United States
(12) Patent Application Publication
(10) Pub. No.: US 2025/0344446 A1
(43) Pub. Date: Nov. 6, 2025

(54) SEMICONDUCTOR DEVICE AND FORMATION METHOD THEREOF

(71) Applicant: TAIWAN SEMICONDUCTOR MANUFACTURING COMPANY, LTD., Hsinchu (TW)

(72) Inventors: Mu-Chieh CHANG, Hsinchu County (TW); Tai-Chun HUANG, Hsinchu City (TW)

(73) Assignee: TAIWAN SEMICONDUCTOR MANUFACTURING COMPANY, LTD., Hsinchu (TW)

(21) Appl. No.: 18/655,769

(22) Filed: May 6, 2024

(51) Int. Cl. H01L 29/423; H01L 21/02; H01L 21/306; H01L 21/311; H01L 21/8238; H01L 27/092; H01L 29/06; H01L 29/66; H01L 29/775; H01L 29/786

(52) U.S. Cl. CPC H10D 30/6735; H01L 21/02211; H01L 21/30604; H01L 21/31111; H10D 30/014; H10D 30/43; H10D 30/6757; H10D 62/118; H10D 64/017; H10D 64/018; H10D 84/0172; H10D 84/038; H10D 84/85

(57) ABSTRACT

A method of forming a semiconductor device comprises the following steps. A fin is formed over a substrate, the fin comprising alternately stacked first semiconductor layers and second semiconductor layers. Sidewalls of the first semiconductor layers are etched to form sidewall recesses. A vapor-phase fill-in material is condensed into a liquid-phase solvent in the sidewall recesses. Precursor gases are dissolved into the liquid-phase solvent. A low-k dielectric material is formed in the sidewall recesses by a chemical reaction using the dissolved precursor gases. The first semiconductor layers are removed to form spaces each between the second semiconductor layers. The spaces are filled with a gate structure.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of gate-all-around field-effect transistors (GAA-FETs) in a three-dimensional view, in accordance with some embodiments.

FIGS. 2-5, 6A, 13A, 14A, 15A, 16A and 17A are cross-sectional views at intermediate fabrication stages, illustrating reference cross-section A-A′ illustrated in FIG. 1 that extends through a gate region along a longitudinal axis of the gate region.

FIGS. 6B, 7B, 8B, 9B, 10B, 12B, 13B, 14B, 15B, 16B and 17B are cross-sectional views at intermediate fabrication stages, illustrating reference cross-section B-B′ illustrated in FIG. 1 that extends through a fin along a longitudinal axis of the fin.

FIGS. 7A, 8A, 9A, 10A, 12A, and 13C are cross-sectional views at intermediate fabrication stages, illustrating reference cross-section C-C′ illustrated in FIG. 1 that extends through source/drain regions along the longitudinal direction of the gate region.

FIG. 10C is an enlarged view illustrating features in either the first device region or the second device regions at intermediate fabrication stages, illustrating reference cross-section B-B′ illustrated in FIG. 1 that extends through a fin along a longitudinal axis of the fin.

FIG. 11A shows a flowchart of a method of forming the inner spacers in accordance with some embodiments.

FIGS. 11B, 11C, 11D and 11E are enlarged views illustrating features in either the first device region or the second device region at intermediate fabrication stages, illustrating reference cross-section B-B′ illustrated in FIG. 1 that extends through a fin along a longitudinal axis of the fin.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. In this disclosure, a source/drain refers to a source and/or a drain. It is noted that in the present disclosure, a source and a drain are interchangeably used and the structures thereof are substantially the same.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

In the GAA transistor structures, inner spacers act as isolation features between source/drain regions and gate structure. Formation of the inner spacers may include, such as, recessing sacrificial layers of a multilayer stack to form recesses, and using a conformal deposition to form a dielectric material in the recesses followed by an anisotropic etch process to remove an excess portion of the dielectric material extending beyond the recesses.

In the process of forming inner spacers within semiconductor devices, a common challenge encountered is the creation of undesired seams within these spacers. These seams represent a structural vulnerability, particularly during the anisotropic etching process, where they can lead to the formation of recessed sidewalls on the inner spacers, compromising the integrity of the device.

To address this issue, the present disclosure in some embodiments provides an improved method for forming inner spacers by leveraging the principle of capillary condensation to deposit a low-k dielectric material. Specifically, this process begins by inducing capillary condensation to transform a vapor-phase fill-in material into its liquid-phase within the recesses for inner spacers. This liquid acts as a solvent, into which precursor gases of a low-k material are dissolved. A low-k dielectric material is then synthesized through a solution-phase chemical reaction involving these dissolved precursors. Subsequently, the liquid-phase solvent is evaporated, leaving behind the formed low-k dielectric material in the recesses in the multilayer stack. The condensed “liquid” within recesses designated for the inner spacers can act as a solvent for reagents of a low-k dielectric. For example, alcohol can be used as the fill-in material, serving as a suitable solvent for the solution-phase reaction between a silane (SiH₄) gas and an H₂O gas, which results in the formation of silicon dioxide (SiO₂). This silicon dioxide then serves as inner spacers in the recesses in the multilayer stack. This approach can effectively eliminate the risk of seam generation. Unlike chemical vapor deposition (CVD) techniques, which are prone to seam formation in the recesses, the use of capillary condensation for the formation of inner spacers promotes a seamless deposition of the low-k dielectric material.

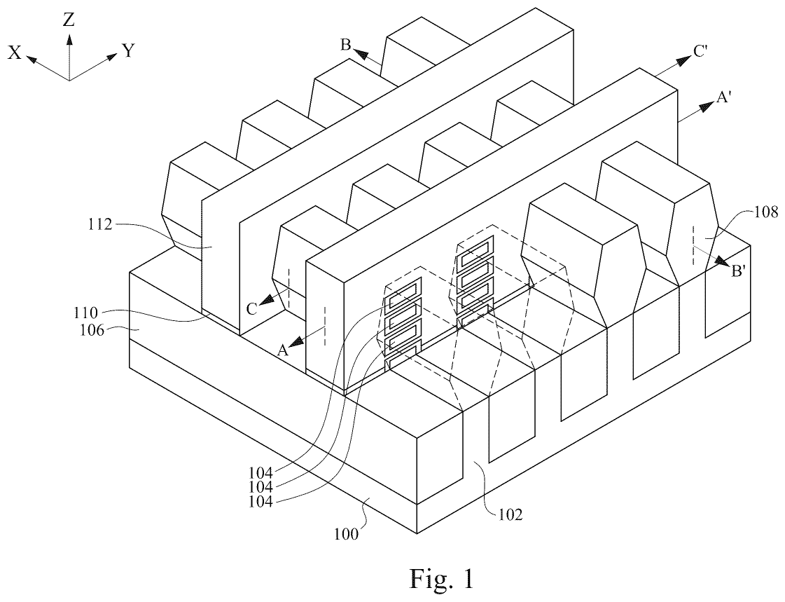

FIG. 1 illustrates an example of GAA-FETs (e.g., nanowire FETs, nanosheet FETs, or the like) in a three-dimensional view, in accordance with some embodiments. As shown, the coordinate system includes an X-axis, Y-axis, and Z-axis. The GAA-FETs comprise nanostructures 104 (e.g., nanosheets, nanowires, nanorings, nanoslabs, or other structures having nano-scale size (e.g., a few nanometers)) over fins 102 on a substrate 100 (e.g., a semiconductor substrate), wherein the nanostructures 104 act as channel regions for the GAA-FETs. The nanostructure 104 may include p-type nanostructures, n-type nanostructures, or a combination thereof. Isolation regions 106 are disposed between adjacent fins 102, which may protrude above and from between neighboring isolation regions 106. Although the isolation regions 106 are described/illustrated as being separate from the substrate 100, as used herein, the term “substrate” may refer to the semiconductor substrate alone or a combination of the semiconductor substrate and the isolation regions. Additionally, although a bottom portion of the fins 102 are illustrated as being single, continuous materials with the substrate 100, the bottom portion of the fins 102 and/or the substrate 100 may comprise a single material or a plurality of materials. In this context, the fins 102 refer to the portion extending between the neighboring isolation regions 106.

Gate dielectrics 110 are over top surfaces of the fins 102 and along top surfaces, sidewalls, and bottom surfaces of the nanostructures 104. Gate electrodes 112 are over the gate dielectrics 110. Epitaxial source/drain regions 108 are disposed on the fins 102 on opposing sides of the gate dielectrics 110 and the gate electrodes 112.

FIG. 1 further illustrates reference cross-sections that are used in later figures. Cross-section A-A′ is along a longitudinal axis of a gate electrode 112 and in a direction, for example, perpendicular to the direction of current flow between the epitaxial source/drain regions 108 of a GAA-FET. That is, the cross-sectional A-A′ is along the y-axis. Cross-section B-B′ is perpendicular to cross-section A-A′ and is parallel to a longitudinal axis of a fin 102 of the GAA-FET and in a direction of, for example, a current flow between the epitaxial source/drain regions 108 of the GAA-FET. That is, the cross-sectional B-B′ is along the x-axis. Cross-section C-C′ is parallel to cross-section A-A′ and extends through epitaxial source/drain regions of the GAA-FETs. That is, the cross-sectional C-C′ is along the y-axis. Subsequent figures refer to these reference cross-sections for clarity. Some embodiments discussed herein are discussed in the context of GAA-FETs formed using a gate-last process. In other embodiments, a gate-first process may be used.

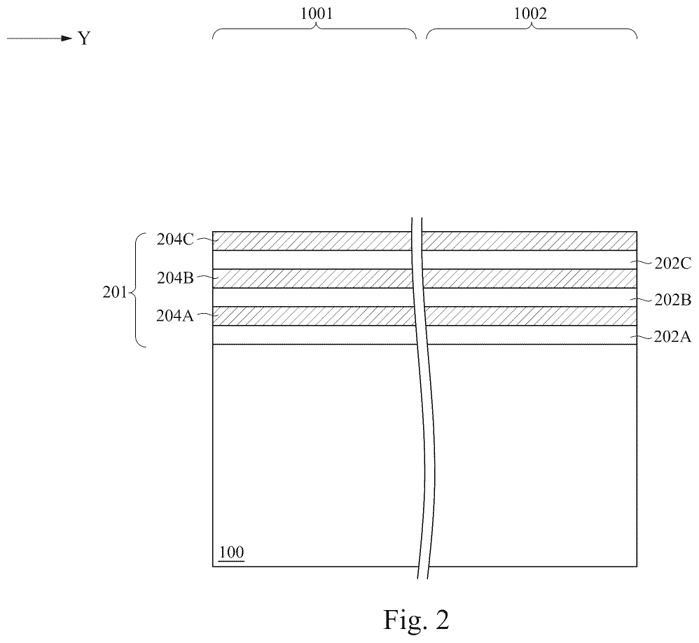

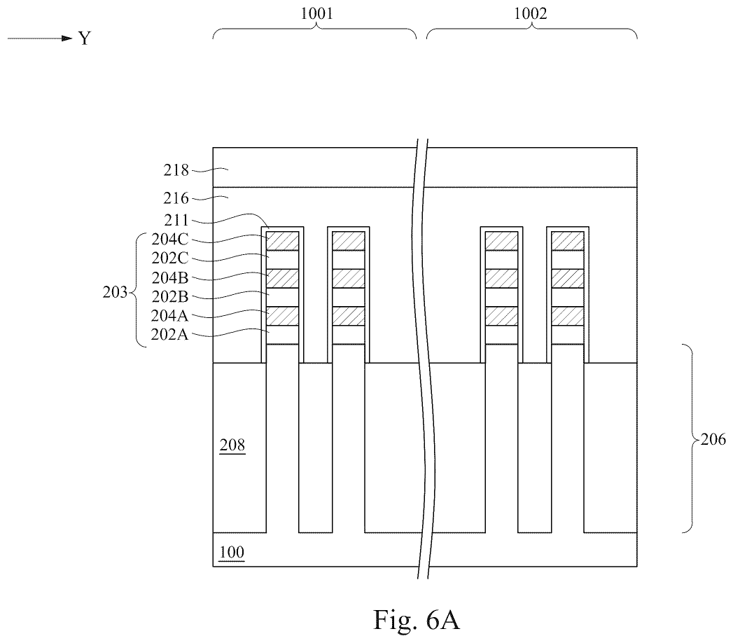

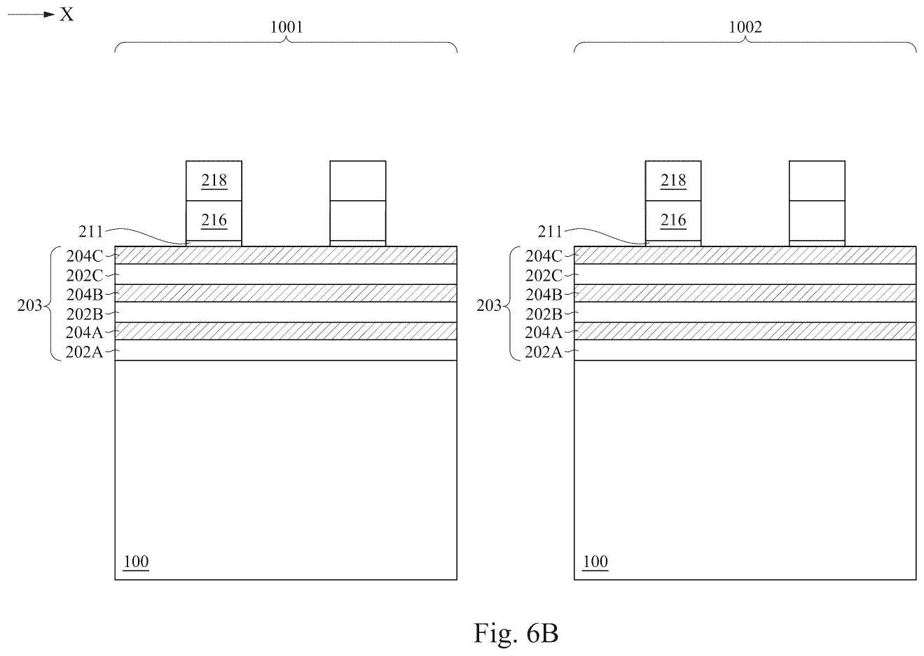

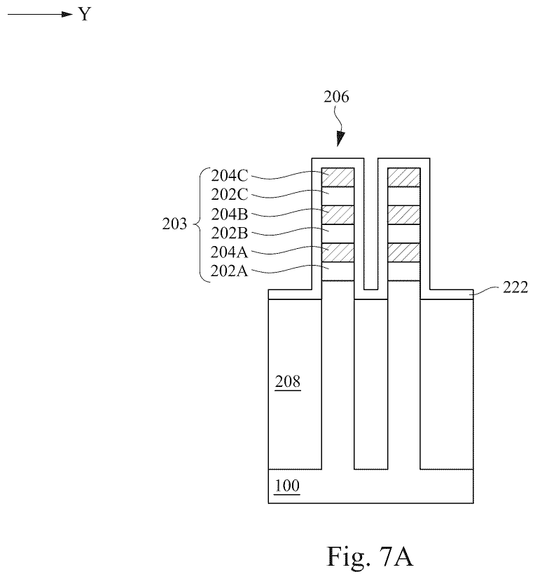

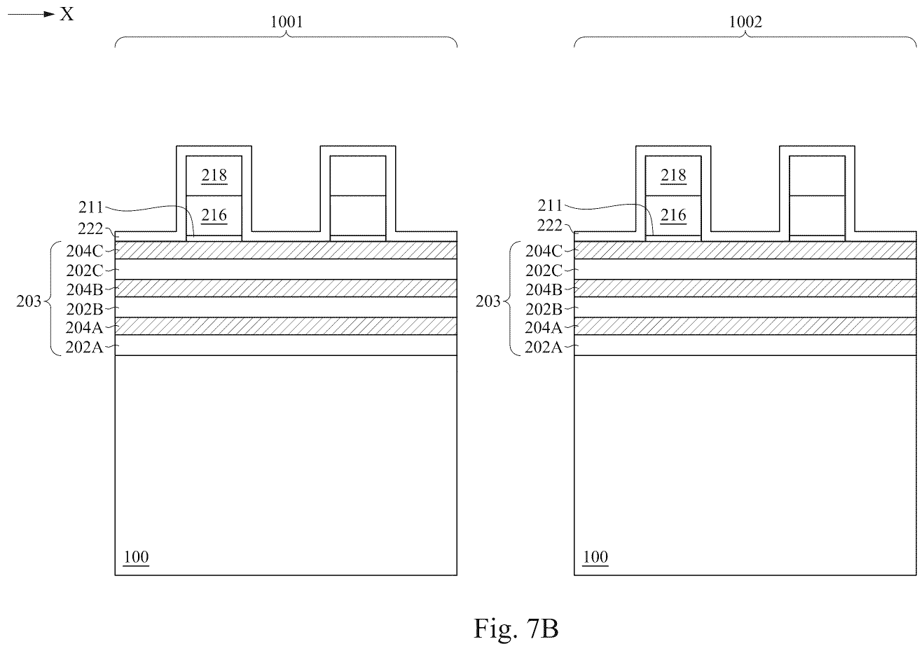

FIGS. 2 through 5, 6A, 13A, 14A, and 15A illustrate reference cross-section A-A′ illustrated in FIG. 1 that extends through a gate region along a longitudinal axis of the gate region. FIGS. 6B, 7B, 8B, 9B, 10B, 12B, 13B, 14B, and 15B illustrate reference cross-section B-B′ illustrated in FIG. 1 that extends through a fin along a longitudinal axis of the fin. FIGS. 7A, 8A, 9A, 10A, 12A, and 13C illustrate reference cross-section C-C′ illustrated in FIG. 1 that extends through source/drain regions along the longitudinal direction of the gate region.

In FIG. 2, a substrate 100 is provided. The substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 100 has a first device region 1001 and a second device region 1002. The first device region 1001 is a region in which first transistors will reside, and the second device region 1002 is a region in which second transistors will reside. In some embodiments, the first transistors are different from the second transistors at least in conductivity type. For example, the first device region 1001 can be for forming n-type devices, such as NMOS transistors, e.g., n-type GAA-FETs, and the second device region 1002 can be for forming p-type devices, such as PMOS transistors, e.g., p-type GAA-FETs. The p-type devices may include a metal gate including a first p-type work function metal layer filling sheet-to-sheet spaces between adjacent nanostructures and a second p-type work function metal layer with thin thickness wrapping the nanostructures, which will be discussed in greater detail below.

The first device region 1001 may be separated from the second device region 1002, and any number of device features (e.g., other active devices, doped regions, isolation structures, etc.) may be disposed between the first device region 1001 and the second device region 1002. Although one first device region 1001 and one second device region 1002 are illustrated, any number of first device regions 1001 and second device regions 1002 may be provided.

Further in FIG. 2, a multi-layer stack 201 is formed over the substrate 100. The multi-layer stack 201 includes alternating layers of first semiconductor layers 202A-C (collectively referred to as first semiconductor layers 202) and second semiconductor layers 204A-C (collectively referred to as second semiconductor layers 204). For purposes of illustration and as discussed in greater detail below, the first semiconductor layers 202 will be removed and the second semiconductor layers 204 will be patterned to form channel regions of GAA-FETs.

The multi-layer stack 201 is illustrated as including three layers of each of the first semiconductor layers 202 and the second semiconductor layers 204 for illustrative purposes. In some embodiments, the multi-layer stack 201 may include any number of the first semiconductor layers 202 and the second semiconductor layers 204. Each of the layers of the multi-layer stack 201 may be epitaxially grown using a process such as chemical vapor deposition (CVD), atomic layer deposition (ALD), vapor phase epitaxy (VPE), molecular beam epitaxy (MBE), or the like. In various embodiments, the second semiconductor layers 204 may be formed of a semiconductor material suitable for serving as channel regions of GAA-FETs, such as silicon, silicon carbon, silicon germanium, or the like.

The first semiconductor materials and the second semiconductor materials may be materials having a high-etch selectivity to one another. As such, the first semiconductor layers 202 of the first semiconductor material may be removed without significantly removing the second semiconductor layers 204 of the second semiconductor material, thereby allowing the second semiconductor layers 204 to serve as channel regions of GAA-FETs.

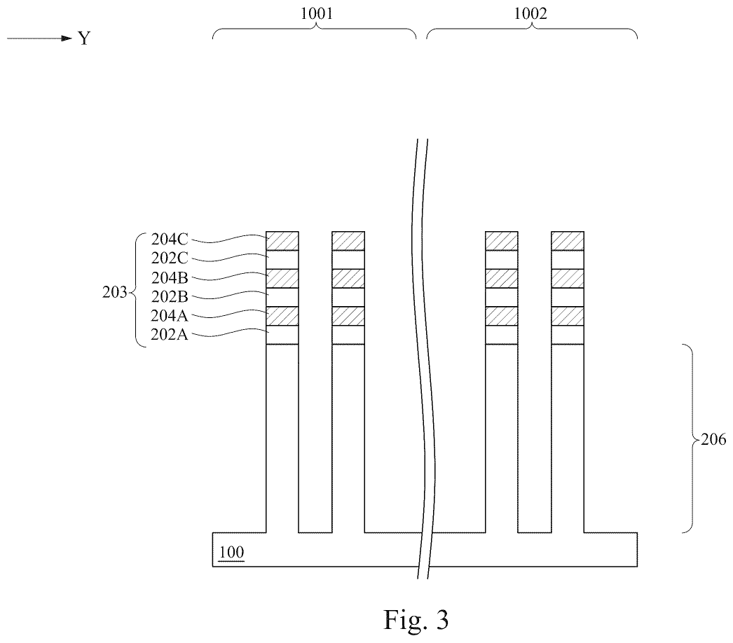

Referring now to FIG. 3, fin structures 206 are formed in the substrate 100 and nanostructures 203 are formed in the multi-layer stack 201, in accordance with some embodiments. In some embodiments, the nanostructures 203 and the fin structures 206 may be formed in the multi-layer stack 201 and the substrate 100, respectively, by etching trenches in the multi-layer stack 201 and the substrate 100. Each fin structure 206 and overlying nanostructures 203 can be collectively referred to as a fin extending from the substrate 100. The etching may be any acceptable etch process, such as a reactive ion etch (RIE), neutral beam etch (NBE), the like, or a combination thereof. The etching may be anisotropic. Forming the nanostructures 203 by etching the multi-layer stack 201 may further define first nanostructures 202A-C (collectively referred to as the first nanostructures 202) from the first semiconductor layers 202 and define second nanostructures 204A-C (collectively referred to as the second nanostructures 204) from the second semiconductor layers 204. The first nanostructures 202 and the second nanostructures 204 may further be collectively referred to as nanostructures 203.

The fin structures 206 and the nanostructures 203 may be patterned by any suitable method. For example, the fin structures 206 and the nanostructures 203 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 206.

FIG. 3 illustrates the fin structures 206 in the first device region 1001 and the second device region 1002 as having substantially equal widths for illustrative purposes. In some embodiments, widths of the fin structures 206 in the first device region 1001 may be greater or thinner than the fin structures 206 in the second device region 1002. Further, while each of the fin structures 206 and the nanostructures 203 are illustrated as having a consistent width throughout, in other embodiments, the fin structures 206 and/or the nanostructures 203 may have tapered sidewalls such that a width of each of the fin structures 206 and/or the nanostructures 203 continuously increases in a direction towards the substrate 100. In such embodiments, each of the nanostructures 203 may have a different width and be trapezoidal in shape.

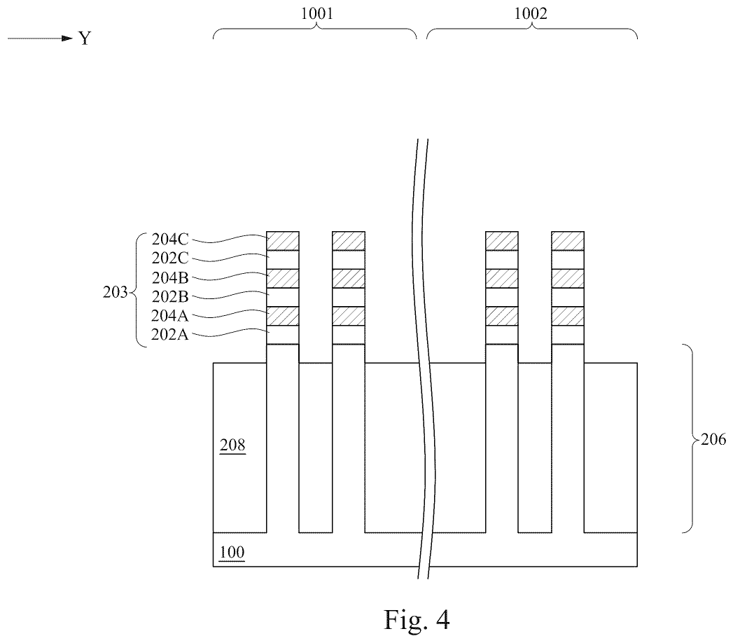

In FIG. 4, shallow trench isolation (STI) regions 208 are formed adjacent the fin structures 206. The STI regions 208 may be formed by depositing an insulation material over the substrate 100, the fin structures 206, and nanostructures 203, and between adjacent fin structures 206. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 203. Although the insulation material is illustrated as a single layer, some embodiments may utilize multiple layers. For example, in some embodiments a liner (not separately illustrated) may first be formed along a surface of the substrate 100, the fin structures 206, and the nanostructures 203. Thereafter, a fill material, such as those discussed above may be formed over the liner.

A removal process is then applied to the insulation material to remove excess insulation material over the nanostructures 203. In some embodiments, a planarization process such as a chemical mechanical polish (CMP), an etch-back process, combinations thereof, or the like may be utilized. The planarization process exposes the nanostructures 203 such that top surfaces of the nanostructures 203 and the insulation material are level after the planarization process is complete.

The insulation material is then recessed to form the STI regions 208. The insulation material is recessed such that upper portions of fin structures 206 in the first and second device regions 1001 and 1002 and protrude from between neighboring STI regions 208. Further, the top surfaces of the STI regions 208 may have a flat surface as illustrated, a convex surface, a concave surface (such as dishing), or a combination thereof. The top surfaces of the STI regions 208 may be formed flat, convex, and/or concave by an appropriate etch. The STI regions 208 may be recessed using an acceptable etching process, such as one that is selective to the material of the insulation material (e.g., etches the material of the insulation material at a faster rate than the material of the fin structures 206 and the nanostructures 203). For example, an oxide removal using, for example, dilute hydrofluoric (dHF) acid may be used.

The process described above with respect to FIGS. 2 through 4 is just one example of how the fin structures 206 and the nanostructures 203 may be formed. In some embodiments, the fin structures 206 and/or the nanostructures 203 may be formed using a mask and an epitaxial growth process. For example, a dielectric layer can be formed over a top surface of the substrate 100, and trenches can be etched through the dielectric layer to expose the underlying substrate 100. Epitaxial structures can be epitaxially grown in the trenches, and the dielectric layer can be recessed such that the epitaxial structures protrude from the dielectric layer to form the fin structures 206 and/or the nanostructures 203. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers (and resulting nanostructures 202) and the second semiconductor layers (and resulting nanostructures 204) are illustrated and discussed herein as comprising the same materials in the second device region 1002 and the first device region 1001 for illustrative purposes only. As such, in some embodiments one or both of the first semiconductor layers and the second semiconductor layers may be different materials or formed in a different order in the first and second device regions 1001 and 1002.

Further in FIG. 4, appropriate wells (not separately illustrated) may be formed in the fin structures 206, the nanostructures 203, and/or the STI regions 208. In some embodiments with different well types in different device regions 1001 and 1002, different implant steps for the first device region 1001 and the second device region 1002 may be achieved using a photoresist or other masks (not separately illustrated). For example, a photoresist may be formed over the fin structures 206 and the STI regions 208 in the first device region 1001 and the second device region 1002. The photoresist is patterned to expose the second device region 1002. The photoresist can be formed by using a spin-on technique and can be patterned using acceptable photolithography techniques. Once the photoresist is patterned, a first impurity (e.g., n-type impurity such as phosphorus, arsenic, antimony, or the like) implant is performed in the second device region 1002, and the photoresist may act as a mask to substantially prevent the first impurities from being implanted into the first device region 1001. After the implant, the photoresist is removed, such as by an acceptable ashing process.

Following or prior to the implanting of the second device region 1002, a photoresist or other masks (not separately illustrated) is formed over the fin structures 206, the nanostructures 203, and the STI regions 208 in the first device region 1001 and the second device region 1002. The photoresist is then patterned to expose the first device region 1001. The photoresist can be formed by using a spin-on technique and can be patterned using acceptable photolithography techniques. Once the photoresist is patterned, a second impurity (e.g., p-type impurity such as boron, boron fluoride, indium, or the like) implant may be performed in the first device region 1001, and the photoresist may act as a mask to substantially prevent p-type impurities from being implanted into the second device region 1002. After the implant, the photoresist may be removed, such as by an acceptable ashing process.

After one or more well implants of the first device region 1001 and the second device region 1002, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

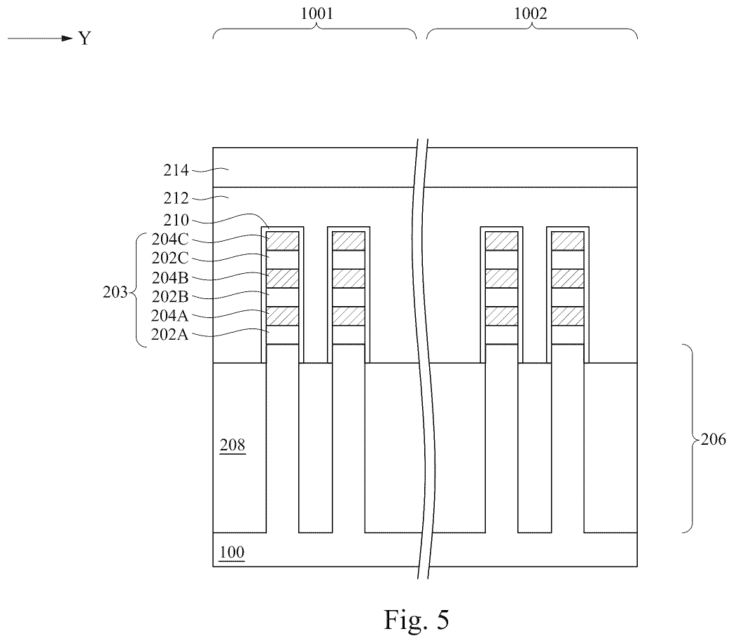

In FIG. 5, a dummy dielectric layer 210 is formed on the fin structures 206 and/or the nanostructures 203. The dummy dielectric layer 210 may be, for example, silicon oxide, silicon nitride, a combination thereof, or the like, and may be deposited or thermally grown according to acceptable techniques. A dummy gate layer 212 is formed over the dummy dielectric layer 210, and a mask layer 214 is formed over the dummy gate layer 212. The dummy gate layer 212 may be deposited over the dummy dielectric layer 210 and then planarized, such as by a CMP. The mask layer 214 may be deposited over the dummy gate layer 212. The dummy gate layer 212 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 212 may be deposited by physical vapor deposition (PVD), CVD, sputter deposition, or other techniques for depositing the selected material. The dummy gate layer 212 may be made of other materials that have a high etching selectivity from the etching of isolation regions. The mask layer 214 may include, for example, silicon nitride, silicon oxynitride, or the like. In this example, a single dummy gate layer 212 and a single mask layer 214 are formed across the first device region 1001 and the second device region 1002. It is noted that the dummy dielectric layer 210 is shown covering only the fin structures 206 and the nanostructures 203 for illustrative purposes only. In some embodiments, the dummy dielectric layer 210 may be deposited such that the dummy dielectric layer 210 covers the STI regions 208, such that the dummy dielectric layer 210 extends between the dummy gate layer 212 and the STI regions 208.

FIGS. 6A through 17B illustrate various following steps in the manufacturing of embodiment devices. FIGS. 6A, 7A, 8A, 9A, 10A, 12A, 13A, 13C, 14A, 15A, 16A and 17A illustrate features in either the first device region 1001 or the second device region 1002. In FIGS. 6A and 6B, the mask layer 214 (see FIG. 5) may be patterned using acceptable photolithography and etching techniques to form masks 218. The pattern of the masks 218 then may be transferred to the dummy gate layer 212 and to the dummy dielectric layer 210 to form dummy gates 216 and dummy gate dielectrics 211, respectively. The dummy gates 216 cover respective channel regions of the fin structures 206. The pattern of the masks 218 may be used to physically separate each of the dummy gates 216 from adjacent dummy gates 216. The dummy gates 216 may also have a lengthwise direction substantially perpendicular to the lengthwise direction of respective fin structures 206.

In FIGS. 7A and 7B, a first spacer layer 220 and a second spacer layer 222 are formed over the structures illustrated in FIGS. 6A and 6B, respectively. The first spacer layer 220 and the second spacer layer 222 will be subsequently patterned to act as spacers for forming self-aligned source/drain regions. In FIGS. 7A and 7B, the first spacer layer 220 is formed on top surfaces of the STI regions 208; top surfaces and sidewalls of the fin structures 206, the nanostructures 203, and the masks 218; and sidewalls of the dummy gates 216 and the dummy gate dielectric 211. The second spacer layer 222 is deposited over the first spacer layer 220. The first spacer layer 220 may be formed of silicon oxide, silicon nitride, silicon oxynitride, or the like, using techniques such as thermal oxidation or deposited by CVD, ALD, or the like. The second spacer layer 222 may be formed of a material having a different etch rate than the material of the first spacer layer 220, such as silicon oxide, silicon nitride, silicon oxynitride, or the like, and may be deposited by CVD, ALD, or the like.

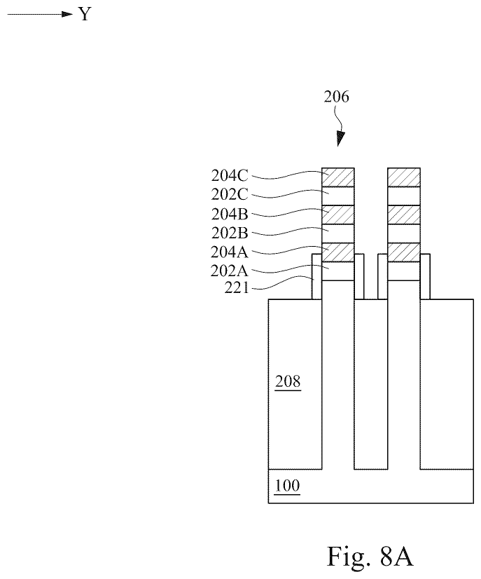

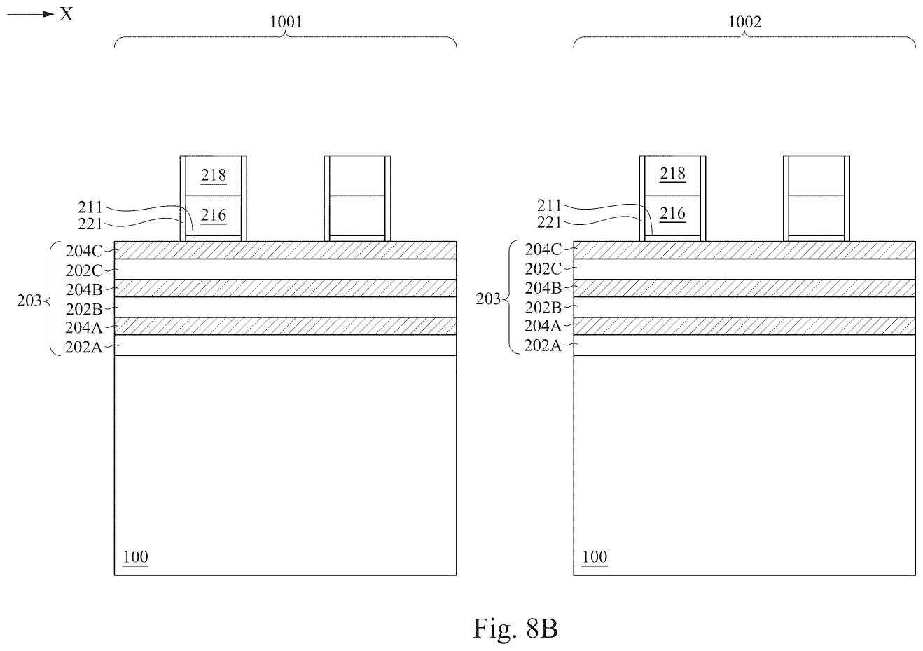

In FIGS. 8A and 8B, the first spacer layer 220 and the second spacer layer 222 are etched to form first spacers 221 and second spacers 223. As will be discussed in greater detail below, the first spacers 221 and the second spacers 223 act to self-align subsequently formed source drain regions, as well as to protect sidewalls of the fin structures 206 and/or nanostructure 203 during subsequent processing. The first spacers 221 can be refer to as gate spacers. The first spacer layer 220 and the second spacer layer 222 may be etched using a suitable etching process, such as an isotropic etching process (e.g., a wet etching process), an anisotropic etching process (e.g., a dry etching process), or the like. In some embodiments, the material of the second spacer layer 222 has a different etch rate than the material of the first spacer layer 220, such that the first spacer layer 220 may act as an etch stop layer when patterning the second spacer layer 222 and such that the second spacer layer 222 may act as a mask when patterning the first spacer layer 220. For example, the second spacer layer 222 may be etched using an anisotropic etch process wherein the first spacer layer 220 acts as an etch stop layer, wherein remaining portions of the second spacer layer 222 form second spacers 223 as illustrated in FIG. 8A. Thereafter, the second spacers 223 acts as a mask while etching exposed portions of the first spacer layer 220, thereby forming first spacers 221 as illustrated in FIG. 8A.

As illustrated in FIG. 8A, the first spacers 221 and the second spacers 223 are disposed on sidewalls of the fin structures 206 and/or nanostructures 203. In some embodiments, the spacers 221 and 223 only partially remain on sidewalls of the fin structures 206. In some embodiments, no spacer remains on sidewalls of the fin structures 206. As illustrated in FIG. 8B, in some embodiments, the second spacer layer 222 may be removed from over the first spacer layer 220 adjacent the masks 218, the dummy gates 216, and the dummy gate dielectrics 211, and the first spacers 221 are disposed on sidewalls of the masks 218, the dummy gates 216, and the dummy gate dielectrics 211. In other embodiments, a portion of the second spacer layer 222 may remain over the first spacer layer 220 adjacent the masks 218, the dummy gates 216, and the dummy gate dielectrics 211.

The above disclosure generally describes a process of forming spacers. Other processes and sequences may be used. For example, fewer or additional spacers may be utilized, different sequence of steps may be utilized (e.g., the first spacers 221 may be patterned prior to depositing the second spacer layer 222), additional spacers may be formed and removed, and/or the like. Furthermore, devices in first device region 1001 and devices in the second device region 1002 may be formed using different structures and steps.

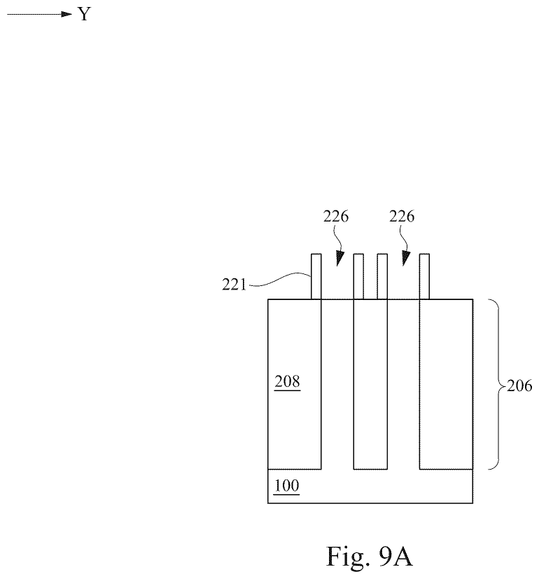

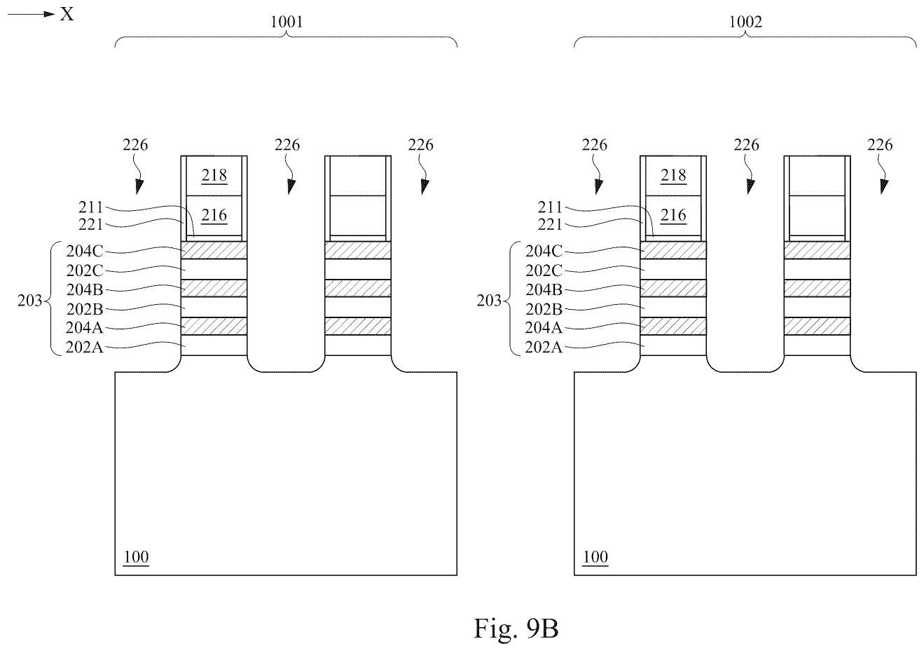

In FIGS. 9A and 9B, source/drain recesses 226 are formed in the fin structures 206, the nanostructures 203, and the substrate 100, in accordance with some embodiments. Epitaxial source/drain regions will be subsequently formed in the source/drain recesses 226. The source/drain recesses 226 may extend through the first nanostructures 202 and the second nanostructures 204, and into the substrate 100. As illustrated in FIG. 9A, bottom surfaces of the source/drain recesses 226 may be level with top surfaces of the STI regions 58, as an example. In some other embodiments, the fin structures 206 may be etched such that bottom surfaces of the source/drain recesses 226 are disposed below the top surfaces of the STI regions 208, or above the top surfaces of the STI regions 208. The source/drain recesses 226 may be formed by etching the fin structures 206, the nanostructures 203, and the substrate 100 using anisotropic etching processes, such as RIE, NBE, or the like. The first spacers 221, the second spacers 223, and the masks 218 mask portions of the fin structures 206, the nanostructures 203, and the substrate 100 during the etching processes used to form the source/drain recesses 226. A single etch process or multiple etch processes may be used to etch each layer of the nanostructures 203 and/or the fin structures 206. Timed etch processes may be used to stop the etching of the source/drain recesses 226 after the source/drain recesses 226 reach a target depth.

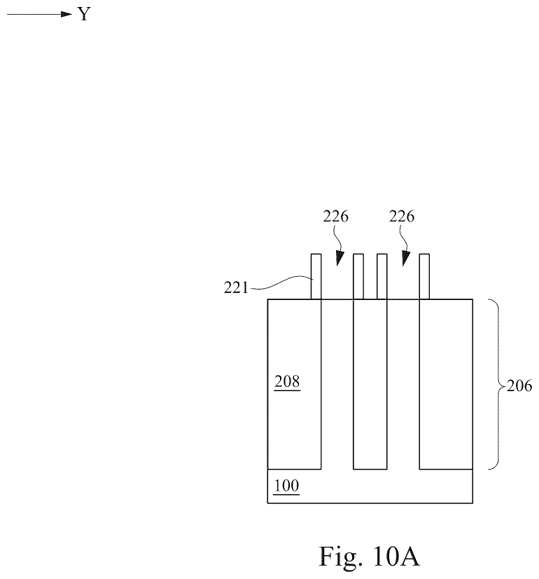

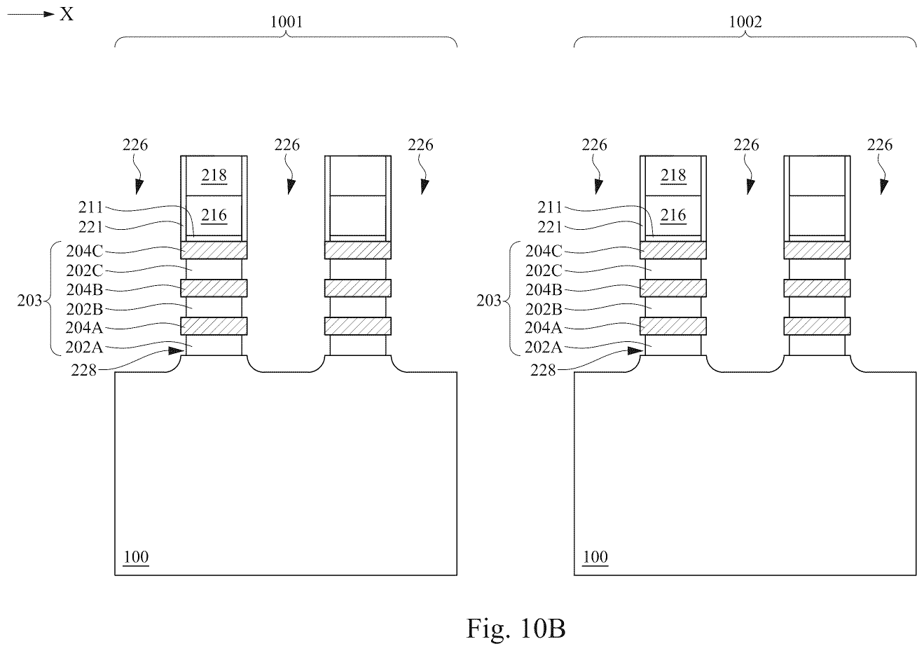

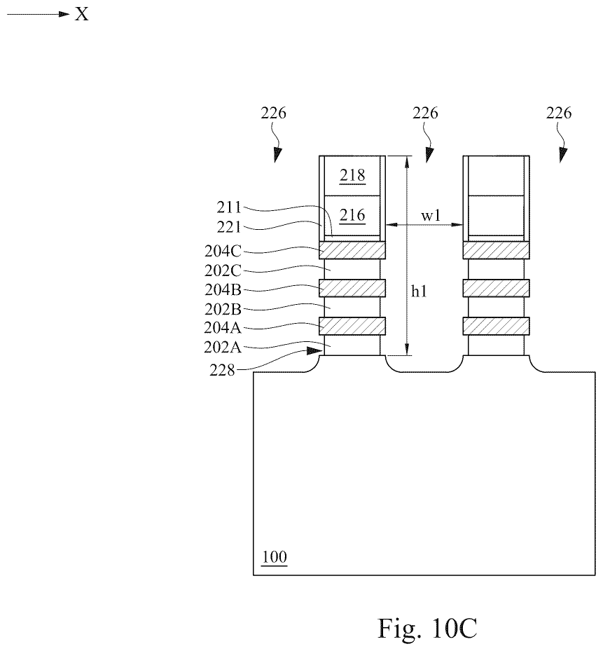

FIG. 10C is an enlarged view illustrating features in either the first device region 1001 or the second device regions 1002 at intermediate fabrication stages, illustrating reference cross-section B-B′ illustrated in FIG. 1 that extends through a fin along a longitudinal axis of the fin. In FIGS. 10A-10C, portions of sidewalls of the layers of the multi-layer stack 201 formed of the first semiconductor materials (e.g., the first nanostructures 202) exposed by the source/drain recesses 226 are etched to form sidewall recesses 228 between corresponding second nanostructures 204. Although sidewalls of the first nanostructures 202 in the sidewall recesses 228 are illustrated as being straight in FIGS. 10B-10C, the sidewalls may be concave or convex. The sidewalls may be etched using isotropic etching processes, such as wet etching or the like. In some embodiments in which the first nanostructures 202 include, e.g., SiGe, and the second nanostructures 204 include, e.g., Si or SiC, a dry etch process with tetramethylammonium hydroxide (TMAH), ammonium hydroxide (NH₄OH), or the like may be used to etch sidewalls of the first nanostructures 202. In some embodiments, the source/drain recesses 226 each have a width w1 in a range from about 2 nm to about 50 nm and has a depth h1. The source/drain recesses 226 may have an aspect ratio (AR) of about 0.5 to 20. Although the source/drain recesses 226 are illustrated as vertical in FIGS. 10B-10C, the source/drain recesses 226 may be lateral or tilting.

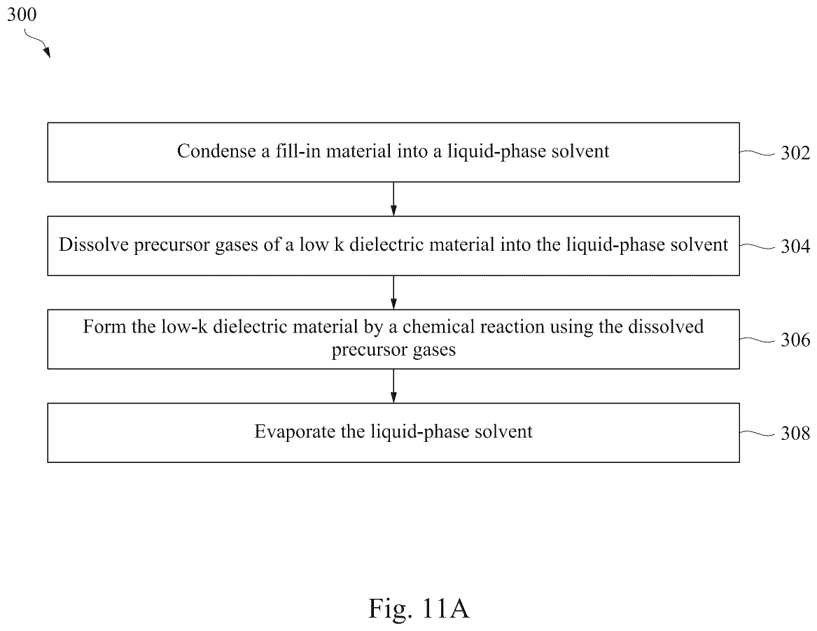

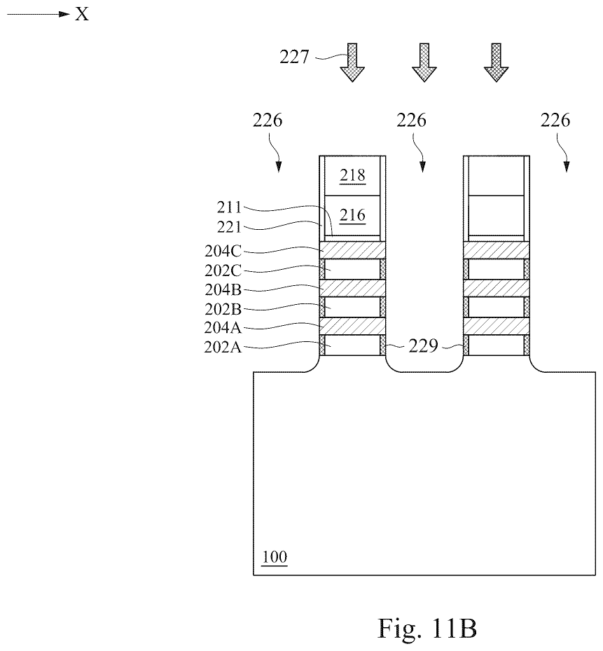

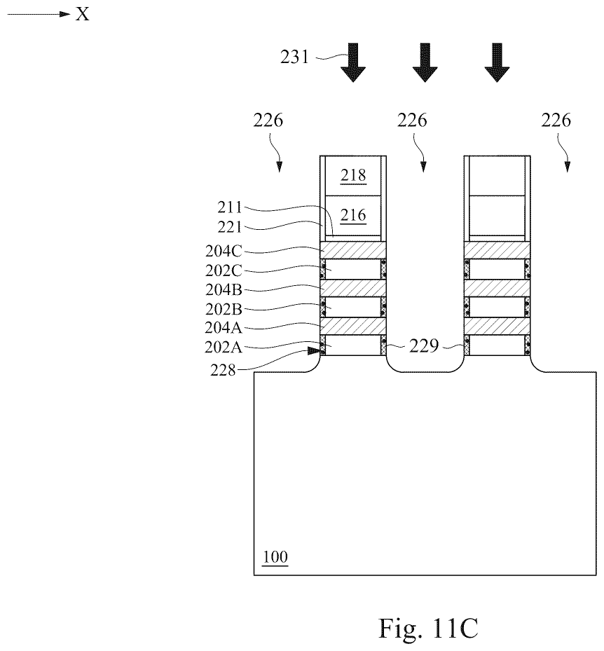

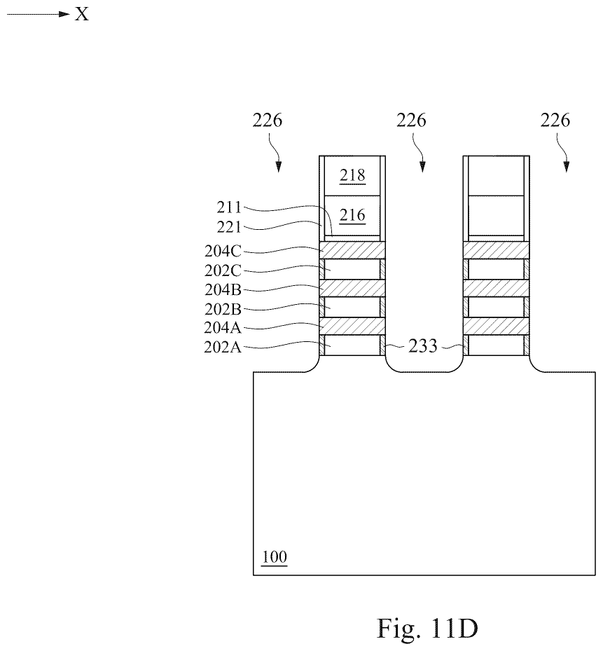

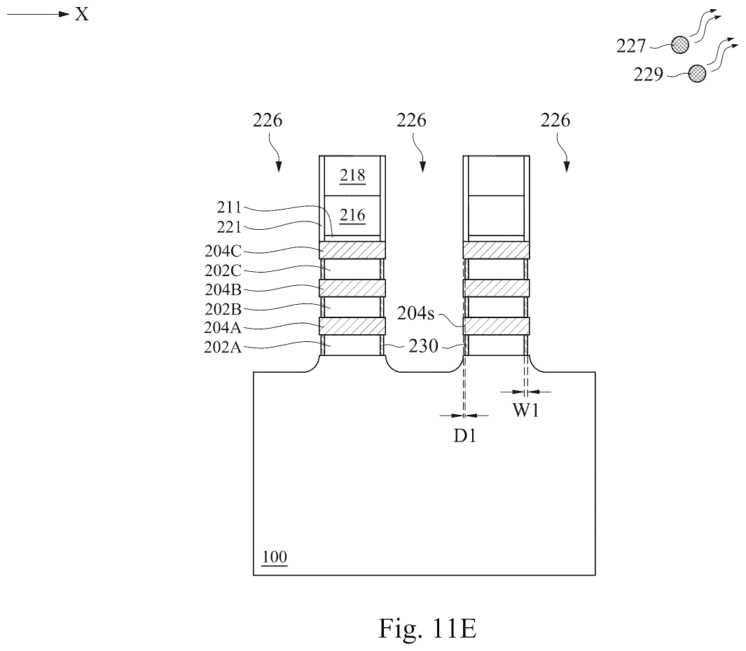

FIG. 11A shows a flowchart of a method 300 of forming inner spacers in the sidewall recess 228 in accordance with some embodiments. FIGS. 11B, 11C, 11D and 11E are enlarged views illustrating features in either the first device region 1001 or the second device region 1002 at intermediate fabrication stages, illustrating reference cross-section B-B′ illustrated in FIG. 1 that extends through a fin along a longitudinal axis of the fin. Reference is made to FIG. 11A. The method 300 begins at an operation 302 where a vapor-phase fill-in material is condensed into a liquid-phase solvent by using capillary condensation. With reference to FIG. 11B, in some embodiments of the operation 302, a vapor-phase fill-in material 227 is condensed into a liquid-phase solvent 229 in the sidewall recesses 228 by using the mechanism of capillary condensation. In the operation 302, the fill-in material 227 can undergo a phase change from a gaseous state to a liquid state by using capillary condensation. Capillary condensation is a phenomenon that occurs within the microscopically small recesses, where the condensation of a vapor phase into a liquid phase happens at a relative humidity lower than the saturation humidity of the bulk material. This process is influenced by the capillary forces present within the confines of the recesses. Generally, the smaller the recess size, the lower the relative humidity required for condensation to start, due to the increased capillary forces pulling the liquid phase into the recesses. Because the sidewall recesses 228 are nano-scaled (dimension of the recesses 228 having only few nanometers), the capillary condensation can be induced under suitable pressure and temperature to transform the vapor-phase fill-in material 227 into a liquid-phase solvent 229 within the sidewall recesses 228. In some embodiments, the capillary condensation can be triggered under a suitable pressure, for example, in a range from about 0.1 torr to about 760 torr, and at temperature, for example, in a range from about −50° C. to about 700° C. Due to the sidewall recesses 228 having a size smaller than a size of the source/drain recesses 226, the capillary condensation phenomenon occurs only in the sidewall recesses 228, and not in other places, such as the source/drain recesses 226. Therefore, the liquid-phase solvent 229 can be “selectively” formed in the sidewall recesses 228.

In some embodiments, the fill-in material 227 may have a low boiling point. In some embodiments, the fill-in material 227 has the boiling point lower than a boiling point of subsequently formed low-k dielectric material. In some embodiments, the fill-in material 227 may have the boiling point such as lower than about 300° C. in order to evaporate effectively after the formation of the low-k dielectric material. For example, the fill-in material 227 may be an inorganic solvent, such as water. That is, the vapor-phase fill-in material 227 may be a vapor-phase water. In some embodiments, the fill-in material 227 may be an organic solvent, such as alcohol, hydrocarbon compound with low molecule weight, or a combination thereof. That is, the vapor-phase fill-in material 227 may be a vapor-phase alcohol, a vapor-phase hydrocarbon compound with low molecule weight, or a combination thereof. In some embodiments, the fill-in material 227 may have a low dielectric constant, such as lower than about 5.0. For example, the fill-in material 227 can be the hydrocarbon compound such as alkane, alkene, alkyne, aromatic compound, ether compound, fluorinated hydrocarbon, or a combination thereof.

Returning back to FIG. 11A, the method 300 then proceeds to an operation 304 where precursor gases of a low-k dielectric material are dissolved into the liquid-phase solvent. With reference to FIG. 11C, in some embodiments of the operation 304, precursor gases 231 of a low-k dielectric material are dissolved into the liquid-phase solvent 229, forming a solution in the sidewall recesses 228. For example, the precursor gases 231 may include a silicon-containing precursor, an oxygen-containing precursor, a carbon-containing precursor, a boron-containing precursor, a nitrogen-containing precursor or other suitable precursor. The silicon-containing precursor, the oxygen-containing precursor, the carbon-containing precursor, the boron-containing precursor, the nitrogen-containing precursor or other suitable precursor can serve as reagents for the formation of the low-k dielectric material to serve as the inner spacers in the sidewall recesses 228. The precursor gases 231 of the low-k dielectric material can be dissolved into the liquid-phase solvent 229 at the same time or in sequence. In some embodiments, the silicon-containing precursor may include Silane (SiH₄), Tris(dimethylamido)silane (3DMASi), Tetrakis(dimethylamido)silane (TDMASi), Bis(diethylamino)silane (BDEAS), bis(tert-butylamido)silane (BTBAS), bis(dimethylamido)silane (BDMAS), bis(ethylmethylamino)silane (BEMAS), Diaminosilane (SiH₂(NH₂)₂), Disilane (Si₂H₆), Dimethyldichlorosilane (DMDCS), Monochlorosilane (MCS), Dichlorosilane (DCS), Hexachlorodisilane (Si₂Cl₆), Di(isopropylamino)silane (DIPAS), Di(sec-butylamino)silane (DSBAS), Tetrakis(ethylamido)silane (TEASi), TetraethylorthoSilicate (TEOS), Tris(isopropyl)aminosilane (TIPAS), Trimethylsilane (TMS), Triisopropylsilane (TIPS), Tris(dimethylamino)chlorosilane (3DMASiCl), Tris(ethylmethylamido)silane (3EMAS), or Trisilylamine (N(SiH₃)₃), other suitable silicon-containing precursor gases, or a combination thereof. The oxygen-containing precursor may be ozone (O₃), oxygen, water (H₂O), N₂O, H₂O—H₂O₂, the like, or a combination thereof. The nitrogen-containing precursor may be NH₃, N₂, the like, or a combination thereof. The carbon-containing precursor may be methane (CH₄), monomethylsilane (SiH₃(CH₃)) (MMS), other suitable carbon-containing precursor gases, or a combination thereof. The boron-containing precursor may be diborane (B₂H₆), boron trifluoride (BF₃), the like, or a combination thereof.

Returning back to FIG. 11A, the method 300 then proceeds to an operation 306 where the low-k dielectric material is formed by a chemical reaction using the dissolved precursor gases. With reference to FIG. 11D, in some embodiments of the operation 306, the low-k dielectric material 233 is formed by a solution-phase chemical reaction using the dissolved precursor gases 231 (see FIG. 11C) dissolved in the solution 229. A solution phase reaction can refer to a chemical process that occurs entirely in a liquid phase, where the reactants (e.g., precursor gases 231) are dissolved in a solvent (i.e., solvent 229) that facilitates their interaction. For instance, the liquid-phase alcohol may be utilized as the solvent 229, creating a conducive environment for the chemical reaction between the silicon-containing precursor (SiH₄) and oxygen-containing precursor (H₂O), which results in the formation of silicon dioxide (SiO₂). This silicon dioxide then serves as the low-k dielectric material 233 for the inner spacers within the recesses of the multilayer stack. In some other embodiments, the low-k dielectric material may include SiCOBN, SiCON, the like, or a combination thereof. In some embodiments, the low-k dielectric material 233 has a k-value less than about 5.0.

Returning back to FIG. 11A, the method 300 then proceeds to an operation 308 where the liquid-phase solvent is evaporated. With reference to FIG. 11E, because the liquid-phase solvent 229 has a low boiling point, the liquid-phase solvent 229 can be evaporated by increasing the temperature to be higher than a boiling point of the liquid-phase solvent 229, reducing the pressure, or a combination thereof. The resulting structure in the sidewall recesses 228 can be referred to as inner spacers 230. The inner spacers 230 are seamless. At least one of the inner spacers 230 is between adjacent two of the second nanostructures 204. In some embodiments, the fill-in material 227 during the operation 302 may have residue outside the sidewall recesses 228, and this residue can also be removed easily during the operation 308. Therefore, an additional etch process such as anisotropic etch process is not required. In some embodiments, the operation 308 is performed by increasing the temperature above about 700° C. and/or reducing the pressure to below about 0.1 torr. In some embodiments, after the operation 308, a portion of the liquid-phase solvent 229 may remain in the inner spacers 230. For example, the resulting inner spacers 230 may include SiO₂, SiCOBN, SiCON as well as the liquid-phase solvent 229. In other words, the inner spacers 230 may include the low-k dielectric material 233 and residue(s) from the liquid-phase solvent 229 such as a hydrocarbon compound, a hydrogen bond, or a combination thereof. The hydrogen bond may be provided by water molecules in which the bonding between lone electron pair on an outermost orbital of an oxygen atom with polarized hydrogen atoms of neighboring water molecules gives rise to intermolecular forces refers to as hydrogen bond. The residues of liquid-phase solvent 229 in the inner spacers 230 can be verified using electron energy loss spectroscopy (EESL), IR analysis, Raman analysis, or other suitable verification method. In some embodiments, the inner spacers 230 may have a k value less than about 5.0. Due to the evaporation of some of the liquid-phase solvent 229 from the low-k dielectric material 233, the inner spacers 230 may have a reduced volume as compared to that before evaporation. In other words, the inner spacers 230 may have a reduced width W1 or be narrowed along the x-axis. That is, the second nanostructures 204 can have a sidewall 204s separated from a sidewall 230s of the inner spacers 230 by a non-zero distance D1 along the x-axis.

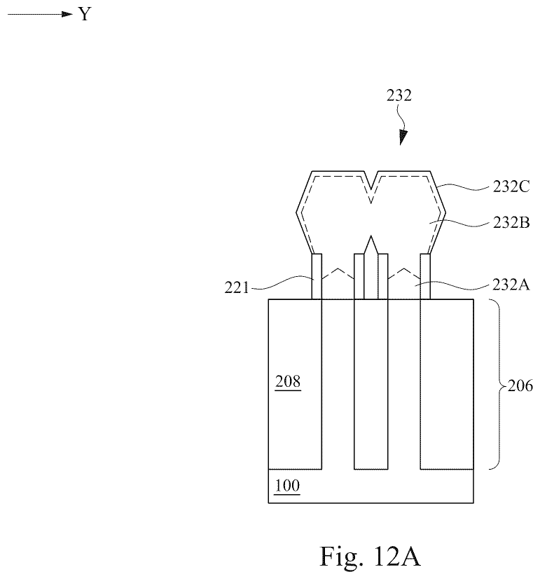

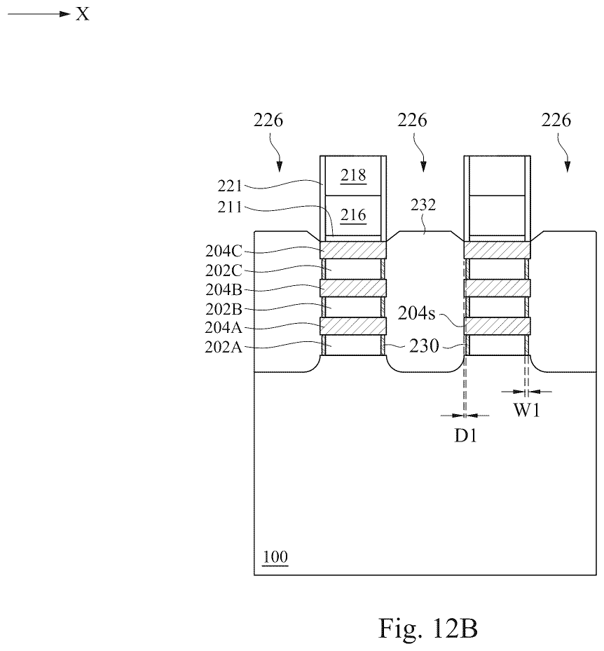

In FIGS. 12A-12B, epitaxial source/drain regions 232 are formed in the source/drain recesses 226. The epitaxial source/drain regions 232 are on opposite sides of the nanostructures 203. In some embodiments, the epitaxial source/drain regions 232 may exert stress on the second nanostructures 204, thereby improving device performance. Since the inner spacers 230 have a reduced width W1 along the x-axis, the epitaxial source/drain regions 232 may have a portion 232p vertically between the second nanostructures 204. The epitaxial source/drain regions 232 are formed in the source/drain recesses 226 such that each dummy gate 216 is disposed between respective neighboring pairs of the epitaxial source/drain regions 232. In some embodiments, the first spacers 221 are used to separate the epitaxial source/drain regions 232 from the dummy gates 216 and the inner spacers 230 are used to separate the epitaxial source/drain regions 232 from the first nanostructures 202 by an appropriate lateral distance so that the epitaxial source/drain regions 232 do not short out with subsequently formed gates of the resulting GAA-FETs.

In some embodiments, the epitaxial source/drain regions 232 may include any acceptable material appropriate for n-type GAA-FETs. For example, if the second nanostructures 204 are silicon, the epitaxial source/drain regions 232 may include materials exerting a tensile strain on the second nanostructures 204, such as silicon carbide, phosphorous doped silicon carbide, silicon phosphide, or the like. In some embodiments, the epitaxial source/drain regions 232 may include any acceptable material appropriate for p-type GAA-FETs. For example, if the second nanostructures 204 are silicon, the epitaxial source/drain regions 232 may comprise materials exerting a compressive strain on the second nanostructures 204, such as silicon germanium, boron doped silicon germanium, germanium, germanium tin, or the like. The epitaxial source/drain regions 232 may have surfaces raised from respective upper surfaces of the nanostructures 203 and may have facets.

The epitaxial source/drain regions 232 may be implanted with dopants to form source/drain regions, followed by an anneal. The n-type and/or p-type impurities for source/drain regions may be any of the impurities previously discussed. In some embodiments, the epitaxial source/drain regions 232 may be in situ doped during growth.

As a result of the epitaxy processes used to form the epitaxial source/drain regions 232, upper surfaces of the epitaxial source/drain regions 232 have facets which expand laterally outward beyond sidewalls of the nanostructures 203. In some embodiments, these facets cause adjacent epitaxial source/drain regions 232 to merge as illustrated by FIG. 12A. In some other embodiments, adjacent epitaxial source/drain regions 232 remain separated after the epitaxy process is completed. In the embodiments illustrated in FIG. 12A, the first spacers 221 may be formed to a top surface of the STI regions 208 thereby blocking the lateral epitaxial growth. In some other embodiments, the first spacers 221 may cover portions of the sidewalls of the nanostructures 203 further blocking the epitaxial growth. In some other embodiments, the spacer etch used to form the first spacers 221 may be adjusted to remove the spacer material to allow the epitaxially grown region to extend to the surface of the STI region 58.

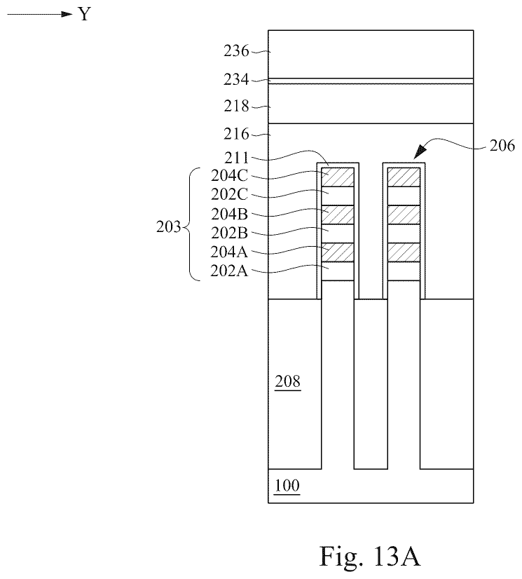

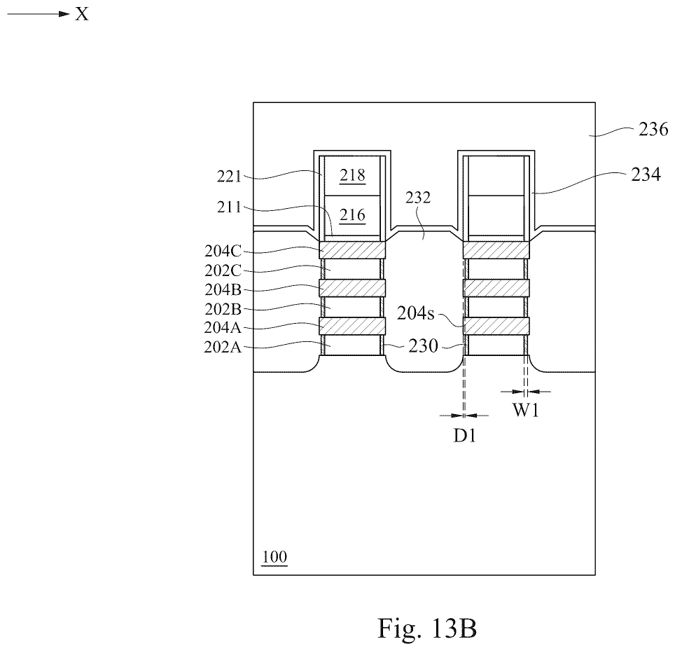

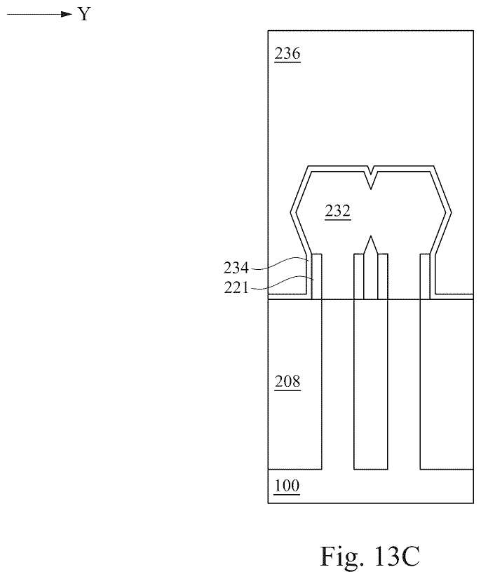

In FIGS. 13A-13C, an interlayer dielectric (ILD) layer 236 is deposited over the structure illustrated in FIGS. 12A-12B. The ILD layer 236 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 234 is disposed between the ILD layer 236 and the epitaxial source/drain regions 232, the masks 218, and the first spacers 221. The CESL 234 may comprise a dielectric material, such as, silicon nitride, silicon oxide, silicon oxynitride, or the like, having a different etch rate than the material of the overlying ILD layer 236.

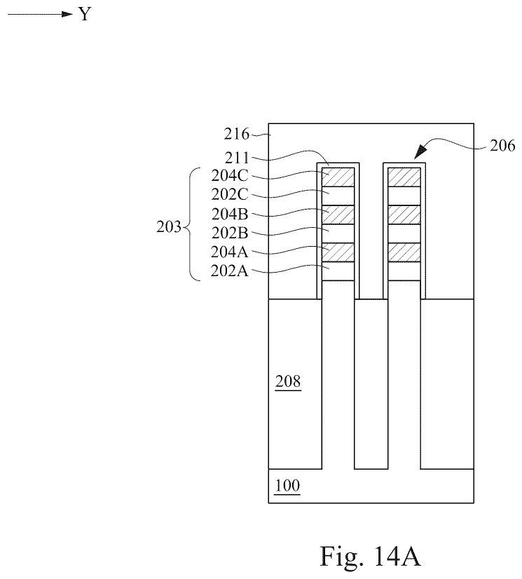

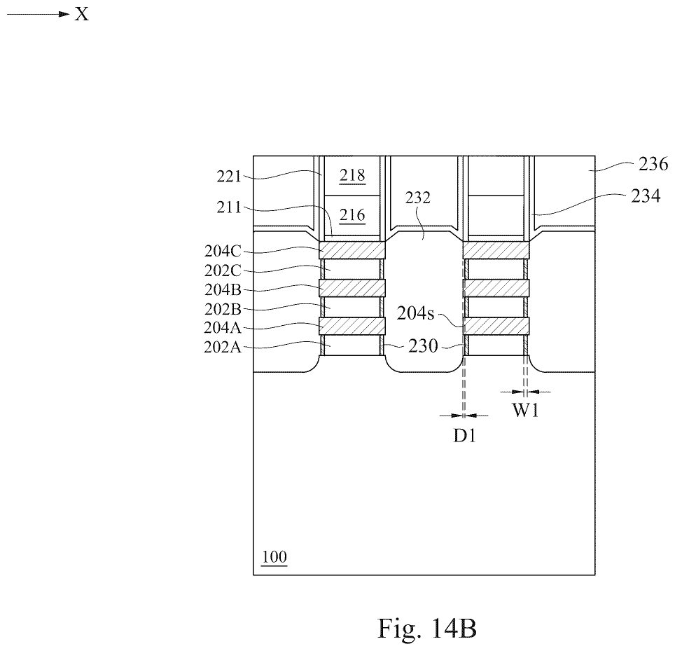

In FIGS. 14A-14B, a planarization process, such as a CMP, may be performed to level the top surface of the ILD layer 236 with the top surfaces of the dummy gates 216 or the masks 218. The planarization process may also remove the masks 218 on the dummy gates 216, and portions of the first spacers 221 along sidewalls of the masks 218. After the planarization process, top surfaces of the dummy gates 216, the first spacers 221, and the ILD layer 236 are level within process variations. Accordingly, the top surfaces of the dummy gates 216 are exposed through the ILD layer 236. In some embodiments, the masks 218 may remain, in which case the planarization process levels the top surface of the ILD layer 236 with top surface of the masks 218 and the first spacers 221.

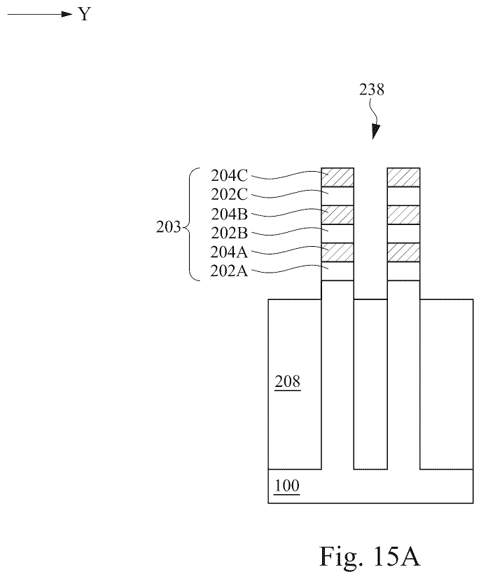

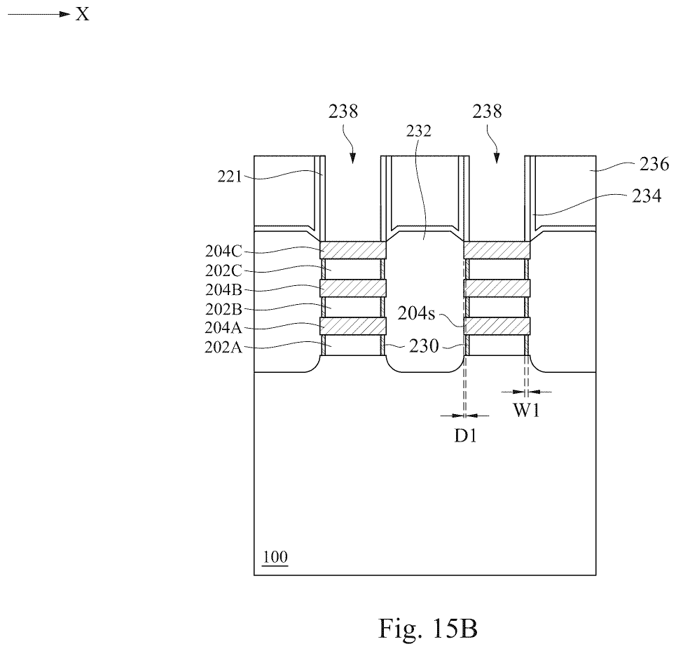

In FIGS. 15A and 15B, the dummy gates 216, and the masks 218 if present, are removed in one or more etching steps, so that gate trenches 238 are formed between corresponding first spacers 221. In some embodiments, portions of the dummy gate dielectrics 211 in the gate trenches 238 are also be removed. In some embodiments, the dummy gates 216 and the dummy gate dielectrics 211 are removed by an anisotropic dry etch process. For example, the etching process may include a dry etch process using reaction gas(es) that selectively etch the dummy gates 216 at a faster rate than the ILD layer 236 or the first spacers 221. Each gate trench 238 exposes and/or overlies portions of nanostructures 204, which act as channel regions in subsequently completed GAA-FETs. The nanostructures 204 which act as the channel regions are disposed between neighboring pairs of the epitaxial source/drain regions 232. During the removal, the dummy gate dielectrics 211 may be used as etch stop layers when the dummy gates 216 are etched. The dummy gate dielectrics 211 may then be removed after the removal of the dummy gates 216.

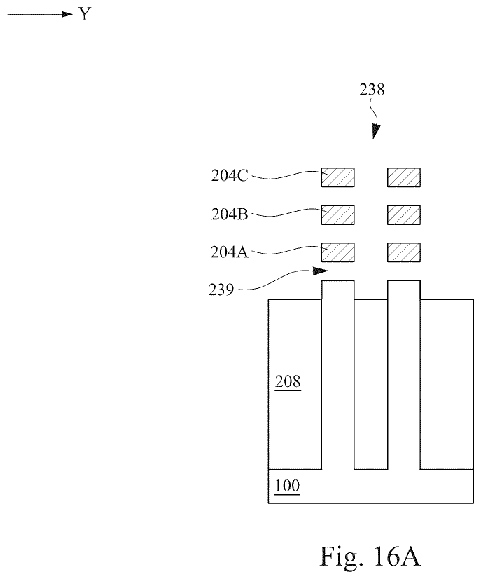

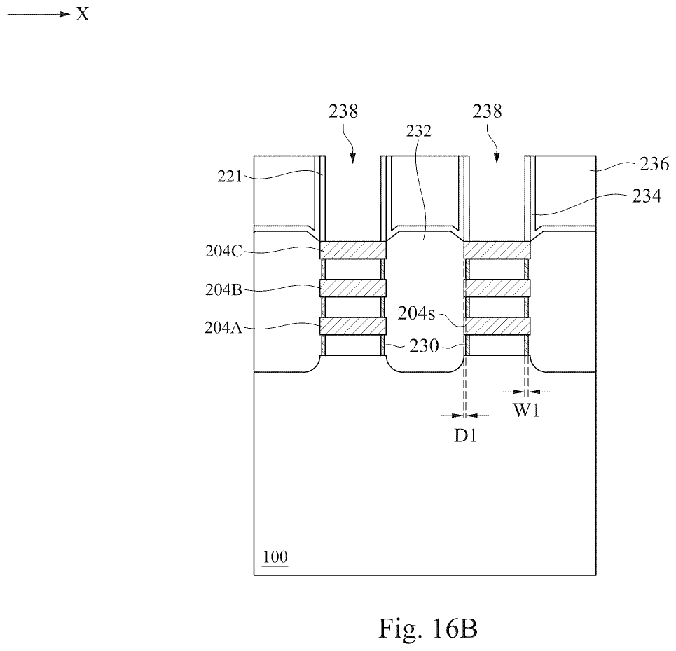

In FIGS. 16A and 16B, the first nanostructures 202 in the gate trenches 238 are removed by an isotropic etching process such as wet etching or the like using etchants which are selective to the materials of the first nanostructures 202. Stated differently, the first nanostructures 202 are removed by using a selective etching process that etches the first nanostructures 202 at a faster etch rate than it etches the second nanostructures 204, thus forming spaces between the second nanostructures 204 (also referred to as sheet-sheet spaces if the nanostructures 204 are nanosheets). This step can be referred to as a channel release process. The second nanostructures 204 extend in the x-axis above the substrate 100 and spaced apart in the z-axis perpendicular to the x-axis. As illustrated in FIGS. 16A and 16B, gaps 239 (empty spaces) are formed between the second nanostructures 204. At this interim processing step, the gaps 239 between second nanostructures 204 may be filled with ambient environment conditions (e.g., air, nitrogen, etc). In some embodiments, the second nanostructures 204 can be referred to as nanosheets, nanowires, nanoslabs, nanorings having nano-scale size (e.g., a few nanometers), depending on their geometry. For example, in some embodiments the second nanostructures 204 may be trimmed to have a substantial rounded shape (i.e., cylindrical) due to the selective etching process for completely removing the first nanostructures 202. In that case, the resultant second nanostructures 204 can be called nanowires.

In embodiments in which the first nanostructures 202 include, e.g., SiGe, and the second nanostructures 204 include, e.g., Si or SiC, tetramethylammonium hydroxide (TMAH), ammonium hydroxide (NH₄OH) or the like may be used to remove the first nanostructures 202. In some embodiments, both the channel release step and the previous step of laterally recessing first nanostructures 202 (i.e., the step as illustrated in FIGS. 10A-10C) use a selective etching process that etches first nanostructures 202 (e.g., SiGe) at a faster etch rate than etching second nanostructures 204 (e.g., Si), and therefore these two steps may use the same etchant chemistry in some embodiments. In this case, the etching time/duration of channel release step is longer than the etching time/duration of the previous step of laterally recessing first nanostructures 202, so as to completely remove the sacrificial nanostructures 202.

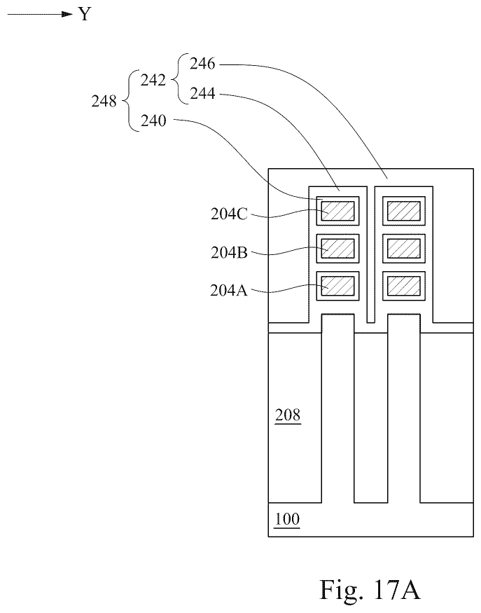

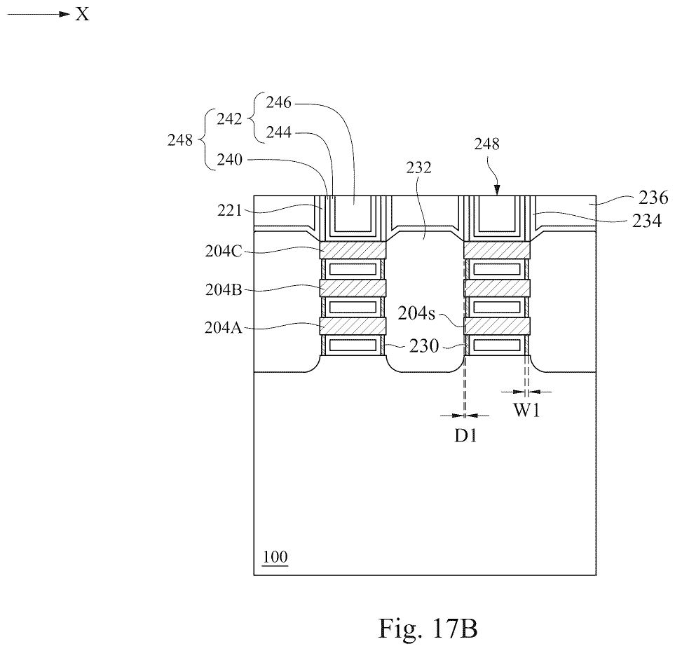

Next, in FIGS. 17A and 17B, high-k/metal gate structures are formed. For example, a gate dielectric layer 240 is formed (e.g., conformally) in the gate trenches 238 and in the gaps 239. The gate dielectric layer 240 wraps around the second nanostructures 204, lines sidewalls of the inner spacers 230 and sidewalls of the first spacers 221, and extends along the upper surface of the fin structures 206. In accordance with some embodiments, the gate dielectric layer 120 comprises silicon oxide, silicon nitride, or multilayers thereof. In some embodiments, the gate dielectric layer 240 includes a high-k dielectric material, and in these embodiments, the gate dielectric layer 240 may have a dielectric constant greater than about 7.0, and may include a metal oxide or a silicate of Hf, Al, Zr, La, Mg, Ba, Ti, or Pb, or combinations thereof. The formation methods of the gate dielectric layer 240 may include Molecular-Beam Deposition (MBD), ALD, PECVD, and the like.

In an alternative embodiment, an interfacial layer (not shown) is deposited between the gate dielectric layer 240 and the second nanostructures 204 and is formed of silicon oxide or silicon oxynitride grown by a thermal oxidation process. For example, the interfacial layer can be grown by a rapid thermal oxidation (RTO) process or by an annealing process using oxygen.

Next, a gate electrode material (e.g., an electrically conductive material) is formed in the gate trenches 238 and in the gaps 239 to form the gate electrodes 242. The gate electrodes 242 fill the remaining portions of the gate trenches 238 and in the gaps 239. For example, the gate electrodes 242 include one or more work function layers 244 and a fill metal layer 246. A CMP is then performed on the fill metal layer 246, the one or more work function layers 244 and the gate dielectric layer 240 until the ILD layer 236 is exposed, resulting in the fill metal layer 246, the one or more work function layers 244 and the gate dielectric layer 240, the CESL 234, and the ILD layer 236 having substantially level top surfaces. The gate electrodes 242 and the gate dielectric layer 240 are collectively referred to as metal gate structures 248.

The one or more work function layers 244 may be deposited to surround each of the second nanostructures 204. A portion of the one or more work function layers 244 is formed vertically between adjacent second nanostructures 204 and fills the gaps 239 between adjacent second nanostructures 204.

The one or more work function layers can provide a suitable work function for the high-k/metal gate structures. For an n-type GAA FET, the one or more work function layers 244 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type GAA FET, the one or more work function layers 244 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the fill metal layer 246 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is seamless inner spacers can be achieved by using capillary condensation. Another advantage is that the low-k dielectric material can be selectively formed in the sidewall recesses in the multilayer stack, and thus additional etching process for removing excess low-k dielectric material outside the sidewall recesses can be omitted.

In some embodiments, a method of forming a semiconductor device comprises the following steps. A fin is formed over a substrate, the fin comprising alternately stacked first semiconductor layers and second semiconductor layers. Sidewalls of the first semiconductor layers are etched to form sidewall recesses. A vapor-phase fill-in material is condensed into a liquid-phase solvent in the sidewall recesses. Precursor gases are dissolved into the liquid-phase solvent. A low-k dielectric material is formed in the sidewall recesses by a chemical reaction using the dissolved precursor gases. The first semiconductor layers are removed to form spaces each between the second semiconductor layers. The spaces are filled with a gate structure. In some embodiments, the method further comprises after forming the low-k dielectric material in the sidewall recesses, evaporating the liquid-phase solvent. In some embodiments, low-k dielectric material has a k value less than about 5.0. In some embodiments, the liquid-phase solvent has a boiling point less than a boiling point of the low-k dielectric material. In some embodiments, the low-k dielectric material comprises SiO₂, SiCOBN, SiCON, or a combination thereof. In some embodiments, the vapor-phase fill-in material comprises vapor-phase water, vapor-phase alcohol, or a vapor-phase hydrocarbon compound. In some embodiments, the precursor gases comprise a silane (SiH₄) gas and an H₂O gas. In some embodiments, the precursor gases are a silicon-containing precursor, an oxygen-containing precursor, a carbon-containing precursor, a boron-containing precursor, a nitrogen-containing precursor or a combination thereof.

In some embodiments, a method of forming a semiconductor device comprises the following steps. A fin is formed over a substrate, the fin comprising alternately stacked first semiconductor layers and second semiconductor layers. Sidewalls of the first semiconductor layers are etched to form sidewall recesses. The sidewall recesses are filled with a solvent. A first precursor is dissolved into the solvent within the sidewall recesses. A second precursor is dissolved into the solvent within the sidewall recesses such that the first precursor and the second precursor react to form inner spacers. The first semiconductor layers are removed to form spaces each between the second semiconductor layers. The spaces are filled with a gate structure. In some embodiments, the first precursor is a silicon-containing precursor. In some embodiments, the second precursor is an oxygen-containing precursor, a carbon-containing precursor, a boron-containing precursor, a nitrogen-containing precursor, or a combination thereof. In some embodiments, the solvent has a boiling point less than about 300° C. In some embodiments, the method further comprises after dissolving the second precursor into the solvent within the sidewall recesses, increasing a temperature to be higher than a boiling point of the solvent. In some embodiments, the solvent comprises water, alcohol, or a hydrocarbon compound. In some embodiments, the hydrocarbon compound includes alkane, alkene, alkyne, aromatic compounds, ether compounds, fluorinated hydrocarbon, or a combination thereof. In some embodiments, the inner spacers comprise SiO₂, SiCOBN, SiCON, or a combination thereof. In some embodiments, the inner spacers further comprise a hydrogen bond or hydrocarbon compound.

In some embodiments, a semiconductor device comprises nanostructures, epitaxial source/drain regions, an inner spacer, and a gate stack. The nanostructures extend in a first direction above a substrate and spaced apart in a second direction perpendicular to the first direction. The epitaxial source/drain regions are on opposite sides of the nanostructures. The inner spacer is between adjacent two of the nanostructures, wherein the inner spacer comprises a hydrocarbon compound, a hydrogen bond or a combination thereof. The gate stack wraps around the nanostructures. In some embodiments, the inner spacer is seamless. In some embodiments, the hydrocarbon compound comprises alcohol, alkane, alkene, alkyne, aromatic compound, ether compound, fluorinated hydrocarbon, or a combination thereof.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, comprising:
forming a fin over a substrate, the fin comprising alternately stacked first semiconductor layers and second semiconductor layers;
etching sidewalls of the first semiconductor layers to form sidewall recesses;
condensing a vapor-phase fill-in material into a liquid-phase solvent in the sidewall recesses;
dissolving precursor gases into the liquid-phase solvent;
forming a low-k dielectric material in the sidewall recesses by a chemical reaction using the dissolved precursor gases;
removing the first semiconductor layers to form spaces each between the second semiconductor layers; and
filling the spaces with a gate structure.

2. The method of claim 1, further comprising:
after forming the low-k dielectric material in the sidewall recesses, evaporating the liquid-phase solvent.

3. The method of claim 1, wherein the low-k dielectric material has a k value less than about 5.0.

4. The method of claim 1, wherein the liquid-phase solvent has a boiling point less than a boiling point of the low-k dielectric material.

5. The method of claim 1, wherein the low-k dielectric material comprises SiO₂, SiCOBN, SiCON, or a combination thereof.

6. The method of claim 1, wherein the vapor-phase fill-in material comprises vapor-phase water, vapor-phase alcohol, or a vapor-phase hydrocarbon compound.

7. The method of claim 1, wherein the precursor gases comprise a silane (SiH₄) gas and an H₂O gas.

8. The method of claim 1, wherein the precursor gases are a silicon-containing precursor, an oxygen-containing precursor, a carbon-containing precursor, a boron-containing precursor, a nitrogen-containing precursor or a combination thereof.

9. A method of forming a semiconductor device, comprising:
forming a fin over a substrate, the fin comprising alternately stacked first semiconductor layers and second semiconductor layers;
etching sidewalls of the first semiconductor layers to form sidewall recesses;
filling the sidewall recesses with a solvent;
dissolving a first precursor into the solvent within the sidewall recesses;
dissolving a second precursor into the solvent within the sidewall recesses such that the first precursor and the second precursor react to form inner spacers;
removing the first semiconductor layers to form spaces each between the second semiconductor layers; and
filling the spaces with a gate structure.

10. The method of claim 9, wherein the first precursor is a silicon-containing precursor.

11. The method of claim 9, wherein the second precursor is an oxygen-containing precursor, a carbon-containing precursor, a boron-containing precursor, a nitrogen-containing precursor, or a combination thereof.

12. The method of claim 9, wherein the solvent has a boiling point less than about 300° C.

13. The method of claim 9, further comprising:
after dissolving the second precursor into the solvent within the sidewall recesses, increasing a temperature to be higher than a boiling point of the solvent.

14. The method of claim 9, wherein the solvent comprises water, alcohol, or a hydrocarbon compound.

15. The method of claim 14, wherein the hydrocarbon compound includes alkane, alkene, alkyne, aromatic compounds, ether compounds, fluorinated hydrocarbon, or a combination thereof.

16. The method of claim 9, wherein the inner spacers comprise SiO₂, SiCOBN, SiCON, or a combination thereof.

17. The method of claim 16, wherein the inner spacers further comprise a hydrogen bond or hydrocarbon compound.

18. A semiconductor device, comprising:
nanostructures extending in a first direction above a substrate and spaced apart in a second direction perpendicular to the first direction;
epitaxial source/drain regions on opposite sides of the nanostructures;
an inner spacer between adjacent two of the nanostructures, wherein the inner spacer comprises a hydrocarbon compound, a hydrogen bond or a combination thereof; and
a gate stack wrapping around the nanostructures.

19. The semiconductor device of claim 18, wherein the inner spacer is seamless.

20. The semiconductor device of claim 18, wherein the hydrocarbon compound comprises alcohol, alkane, alkene, alkyne, aromatic compound, ether compound, fluorinated hydrocarbon, or a combination thereof.
